(19) United States
(12) Patent Application Publication
(10) Pub. No.: US 2008/0111209 A1
(43) Pub. Date: May 15, 2008

(54) SEMICONDUCTOR DEVICE AND ITS MANUFACTURING METHOD

(75) Inventor: Chihiro Shin, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/924,061

(22) Filed: Oct. 25, 2007

(30) Foreign Application Priority Data
Nov. 15, 2006 (JP) 2006-309196

(51) Int. Cl. H01L 29/00; H01L 21/76

(52) U.S. Cl. 257/516; 438/439; 257/E21.54; 257/E29.001

(57) ABSTRACT

A semiconductor device includes: a first element isolation film that is formed by a LOCOS oxidation method on a semiconductor substrate for isolating a first element region from other regions; a second element isolation film embedded in a groove formed in the semiconductor substrate for isolating a second element region from other regions; a first semiconductor element formed in the first element region; a second semiconductor element formed in the second element region; and a resistance element formed on the first element isolation film.

The entire disclosure of Japanese Patent Application No. 2006-309196, filed Nov. 15, 2006 is expressly incorporated by reference herein.

### BACKGROUND

1. Technical Field

The present invention relates to a method for manufacturing a semiconductor device. More particularly, the invention relates to a semiconductor device with an improved dielectric strength between a resistance element and a semiconductor substrate, and its manufacturing method.

2. Related Art

FIG. 4 is a cross-sectional view of a prior art semiconductor device shown for describing its structure. Transistors are formed in element regions 100a and 100b of a silicon substrate 100. The transistor formed in the element region 100a is a part of an on/off signal generation circuit that generates an on/off signal that turns on and off the gate of a TFT provided outside of the semiconductor device. The voltage of the on/off signal is, for example, 10V or higher. The transistor formed in the element region 100b is a part of a control circuit that controls the on/off signal generation circuit, and its operating voltage is, for example, 1.5V. An element isolation film 102a in the element region 100a is formed by a LOCOS oxidation method, and an element isolation film 102b in the element region 100b is formed by a trench isolation method, both of which are embedded in the silicon substrate 100.

Also, in the element region 100c of the silicon substrate 100 and its surrounding area are provided a protection circuit that protects the on/off signal generation circuit from a high voltage noise current that may be impressed from outside. The protection circuit has a transistor for discharging noise currents to the ground, and a polysilicon resistance element 104d located, in the circuit, between the transistor and the on/off signal generation circuit. The resistance element 104d is located on the element isolation film 102b formed by a trench isolation method. Japanese Laid-open Patent Application JP-A-2002-261244 (FIG. 1) may be an example of related art in which a resistance element is formed on an element isolation film formed by a trench isolation method.

During normal operation, a relatively high voltage (for example, 10V or higher) may often be applied to the resistance element. For this reason, the element isolation film located between the resistance element and the semiconductor substrate needs a high dielectric strength. However, the element isolation film formed by a trench isolation method is deposited by a CVD method, and may have micro scratches and Si pits on its surface as a CMP method is applied. For this reasons, an element isolation film formed by a trench isolation method may not be able to secure a sufficient dielectric strength. For example, when a resistance element is a part of a protection circuit for a semiconductor element, it is possible that a dielectric breakdown may occur between the resistance element and the semiconductor substrate by a normal operation voltage, not by a high voltage noise current.

### SUMMARY

In accordance with an advantage of some aspects of the invention, a semiconductor device with an improved dielectric strength between a resistance element and a semiconductor substrate and a method for manufacturing the same can be provided.

A semiconductor device in accordance with an embodiment of the invention includes: a first element isolation film that is formed by a LOCOS oxidation method on a semiconductor substrate for isolating a first element region from other regions; a second element isolation film embedded in a groove formed in the semiconductor substrate for isolating a second element region from other regions; a first semiconductor element formed in the first element region; a second semiconductor element formed in the second element region; and a resistance element formed on the first element isolation film.

In the semiconductor device, the resistance element is formed on the first element isolation film. Therefore, the dielectric strength between the resistance element and the semiconductor substrate can be improved.

The first semiconductor element may be connected to one end of the resistance element. In this case, the semiconductor device may be equipped with an external connection terminal formed above the semiconductor substrate, a wiring that connects the other side of the resistance element and the external connection terminal, and a discharge element formed on the semiconductor substrate and connected to the wiring for protecting the first semiconductor element by discharging a noise current applied from the external connection terminal to ground.

The first semiconductor element may be, for example, a part of an on/off signal generation circuit that generates a signal that turns on and off a gate of a TFT provided outside the semiconductor substrate, and the second semiconductor element may be, for example, a part of a control circuit that controls the on/off signal generation circuit. In normal operation, a high voltage is not applied to the control circuit, but a relatively high voltage (for example, 10V or higher) is applied to the on/off signal generation circuit. If the dielectric strength of the element isolation film located below the first semiconductor element is low, the dielectric state between the element isolation film and the semiconductor substrate may be destroyed during normal operation. However, according to the invention, the dielectric breakdown can be suppressed.

A method for manufacturing a semiconductor device in accordance with an embodiment of the invention includes the steps of: isolating a first element region from other regions by forming a first element isolation film on a semiconductor substrate by using a LOCOS oxidation method; isolating a second element region from other regions by forming a groove in the semiconductor substrate and embedding a second element isolation film in the groove; forming a first semiconductor element in the first element region and forming a second semiconductor element in the second element region; and forming a resistance element on the first element isolation film.

The step of embedding the second element isolation film in the groove may include, for example, forming a dielectric film in the groove, on the first element isolation film and on the semiconductor substrate, and removing the dielectric film located on the first element isolation film and on the semiconductor substrate by a CMP method.

### BRIEF DESCRIPTION OF THE DRAWINGS

FIGS. 1A-1D are cross-sectional views for describing a method for manufacturing a semiconductor device in accordance with a first embodiment of the invention.

FIG. 2 is a circuit diagram in part of a semiconductor device in accordance with the first embodiment.

FIGS. 3A-3D are cross-sectional views for describing a method for manufacturing a semiconductor device in accordance with a second embodiment of the invention.

FIG. 4 is a cross-sectional view for describing the structure of a semiconductor device in prior art.

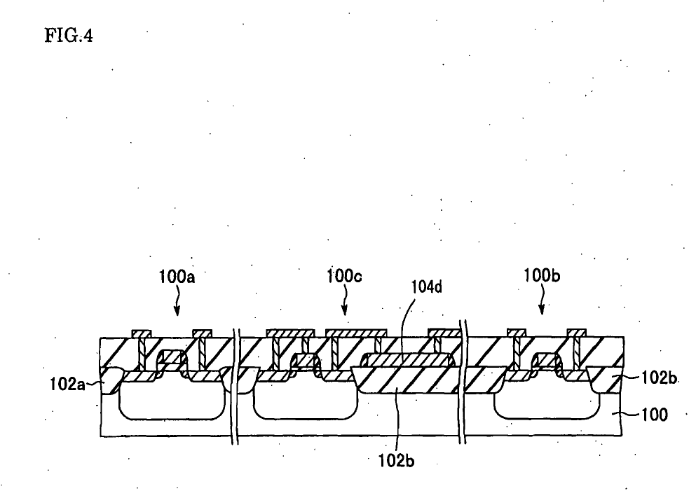

### DESCRIPTION OF EXEMPLARY EMBODIMENTS

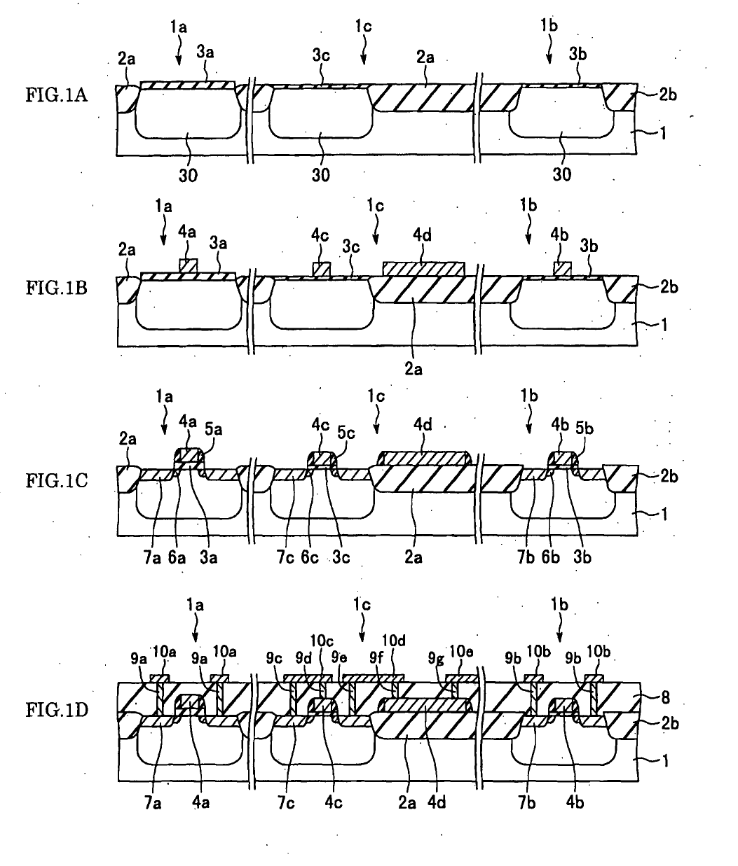

Methods for manufacturing a ferroelectric memory device in accordance with embodiments of the invention are described below with reference to the accompanying drawings. FIGS. 1A-1D are cross-sectional views for describing a method for manufacturing a semiconductor device in accordance with a first embodiment of the invention. The semiconductor device manufactured by the method may be, for example, a driver for a liquid crystal display device.

First, as shown in FIG. 1A, an impurity of a first conductivity type is introduced in a silicon substrate 1, thereby forming wells 30. Next, a mask film (not shown) is formed on the silicon substrate 1, and the silicon substrate is thermally oxidized, using the mask film as a mask. By this, an element isolation film 2a is formed in portions of the silicon substrate 1, such that element regions 1a and 1c are isolated from other regions. In the element region 1a, a transistor is formed by a process described below. The transistor is a part of an on/off signal generation circuit that generates a signal that turns on and off a gate of a TFT of the liquid crystal display panel. In the element region 1c, a transistor is formed by a process described below. The transistor is a part of a protection circuit that protects the transistor formed in the element region 1a. Then, the mask film is removed.

Next, a mask film (not shown) is formed on the silicon substrate 1 and the element isolation film 2a, and the silicon substrate 1 is etched by using the mask film as a mask. By this step, grooves are formed in the silicon substrate 1. Thereafter, the mask film is removed. Then, a dielectric film (for example, a silicon oxide film) is formed by a CVD method in the grooves, on the silicon substrate 1 and on the element isolation film 2a, and the dielectric film located on the silicon substrate 1 and the element isolation film 2a is polished and removed by a CMP method. By this step, an element isolation film 2b is embedded in the grooves of the silicon substrate 1, and an element region 1b is isolated from other regions. In the element region 1b, a transistor is formed by a process to be described below. This transistor is a part of a control circuit that controls the on/off signal generation circuit. Then, the mask film is removed.

Next, the silicon substrate 1 located in the element regions 1b and 1c is covered by a mask film (not shown), and the silicon substrate 1 is thermally oxidized. By this, a gate dielectric film 3a is formed on the silicon substrate 1 in a portion located in the element region 1a. Thereafter, the mask film is removed. Then, the silicon substrate 1 is thermally oxidized. By this, gate dielectric films 3b and 3c are formed on the silicon substrate 1 located in the element regions 1b and 1c. Also, the gate dielectric film 3a becomes thicker in a portion located in the element region 1a.

Then, referring to FIG. 1B, a polysilicon film is formed by a CVD method on the gate dielectric films 3a, 3b and 3c, and on the element isolation films 2a and 2b. Then, a resist pattern is formed on the polysilicon film, and the polysilicon film is etched by using the resist pattern as a mask. By this, the polysilicon film is selectively removed, whereby gate electrodes 4a, 4b and 4c positioned on the gate dielectric films 3a, 3b and 3c, respectively, and a resistance element 4d positioned on the element isolation film 2a are formed. The resistance element 4d is positioned near the element region 1c, and forms, together with a transistor to be formed in the element region 1c, a part of the protection circuit.

Then, referring to FIG. 1C, an impurity of a second conductivity type is introduced in the silicon substrate 1 by using the gate electrodes 4a, 4b and 4c, and the element isolation films 2a and 2b, as masks. By this, low concentration impurity regions 6a, 6b and 6c are formed in the silicon substrate 1 in areas located in the element regions 1a, 1b and 1c, respectively. Then, a dielectric film is formed by a CVD method on the entire surface including the gate electrodes 4a, 4b and 4c, and the dielectric film is etched back. By this, sidewalls 5a, 5b and 5c that cover side walls of the gate electrodes 4a, 4b and 4c, respectively, are formed. Then, an impurity of a second conductivity type is introduced in the silicon substrate 1 by using the sidewalls 5a, 5b and 5c, the gate electrodes 4a, 4b and 4c, and the element isolation films 2a and 2b as masks. By this, impurity regions 7a, 7b and 7c that function as a source and a drain of each of the respective transistors are formed in the silicon substrate 1 located in the element regions 1a, 1b and 1c, respectively.

In this manner, transistors are formed in the element regions 1a, 1b and 1c, respectively. It is noted that CMOS transistors may be formed in the element regions 1a and 1b.

Then, referring to FIG. 1D, an interlayer dielectric film 8 is formed on the entire surface including areas over the transistors and resistance element 4d. Then, a resist pattern (not shown) is formed on the interlayer dielectric film 8, and the interlayer dielectric film 8 is etched by using the resist pattern as a mask. By this, a plurality of connection holes positioned over the respective transistors and a plurality of connection holes positioned over the resistance elements 4d are formed in the interlayer dielectric film 8. Then, a tungsten film is formed by a CVD method in the connection holes and on the interlayer dielectric film 8, and the tungsten film positioned on the interlayer dielectric film 8 is removed by a CMP method. By this, tungsten plugs 9a, 9b, 9c, 9d, 9e and 9f are embedded in the interlayer dielectric film 8. The tungsten plugs 9a connect to the transistor (for example, the impurity regions 7a) located in the element region 1a, and the tungsten plugs 9b connect to the transistor (for example, the impurity regions 7b) located in the element region 1b. The tungsten plug 9c connects to one of the impurity regions 7c of the transistor located in the element region 1c, and the tungsten plug 9d connects to the gate electrode 4c of the transistor located in the element region 1c. The tungsten plug 9e connects to the other of the impurity regions 7c of the transistor located in the element region 1c. The tungsten plug 9e connects to one of end sections of the resistance element 4d, and the tungsten plug 9g connects to the other end section of the resistance element 4d.

Then, an Al alloy film is formed by a sputter method on the respective tungsten plugs and on the interlayer dielectric film 8, and the Al alloy film is selectively removed. By this, Al alloy wirings 10a, 10b, 10c, 10d and 10e are formed on the interlayer dielectric film 8. The Al alloy wirings 10a and 10b connect to the tungsten plugs 9a and 9b, respectively. The Al alloy wiring 10c mutually connects the gate and one of the impurity regions 7c of the transistor located in the element region 1c through the tungsten plugs 9c and 9d. The Al alloy wiring 10d mutually connects the other of the impurity regions 7c of the transistor located in the element region 1c and the resistance element 4d through the tungsten plugs 9e and 9f. Also, the Al alloy wiring 10d connects the resistance element 4d to a pad (not shown). The Al alloy wiring 10e connects the resistance element 4d to the impurity region 7a of the transistor located in the element region 1a through an unshown wiring.

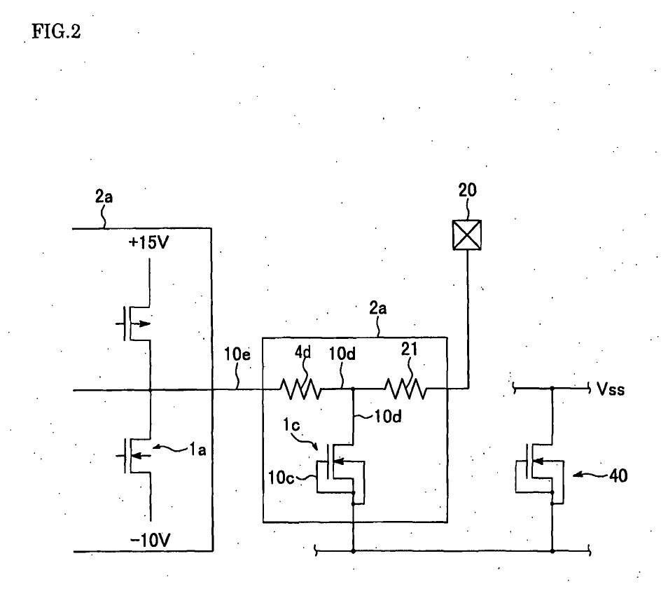

FIG. 2 is a circuit diagram showing a part of the semiconductor device shown in FIG. 1D. As shown in FIG. 2, the resistance element 4d is located, in the circuit, between the transistor located in the element region 1c and the transistor located in the element region 1a. The Al alloy wiring 10d connects the resistance element 4d and the transistor located in the element region 1c to a pad 20 through a resistance element 21.

By the circuit structure described above, the transistor located in the element region 1c functions as a protection element that discharges a noise current at a high voltage flowing through the pad 20 to the ground through a source potential of a transistor 40 in an output stage. Also, the transistor located in the element region 1a is connected to the pad 20 through a wiring, and the resistance element 4d is located, among the wiring connecting the transistor located in the element region 1a and the pad 20, between a portion thereof to which the transistor located in the element region 1c is connected and the transistor located in the element region 1a. For this reason, the resistance element 4d suppresses a noise current from flowing in the transistor formed in the element region 1a.

According to the embodiment of the invention described above, the resistance element 4d that is a part of the protection circuit for the transistor located in the element region 1a is formed on the element isolation film 2a formed by a LOCOS method. Because the transistor located in the element region 1a is a part of the on/off signal generation circuit that generates a signal that turns on and off the gate of the TFT of the liquid display panel, a relatively high voltage (for example, 10V or higher) is applied to the resistance element 4d during normal operation. However, the element isolation film 2a, as it is formed by a LOCOS method, has few deficiencies, and maintains a high dielectric strength even when micro-scratches and Si pits are formed. For this reason, the dielectric strength between the resistance element 4d and the silicon substrate 1 is high, and the occurrence of dielectric breakdown between the resistance element 4d and the silicon substrate 1 can be suppressed during normal operation.

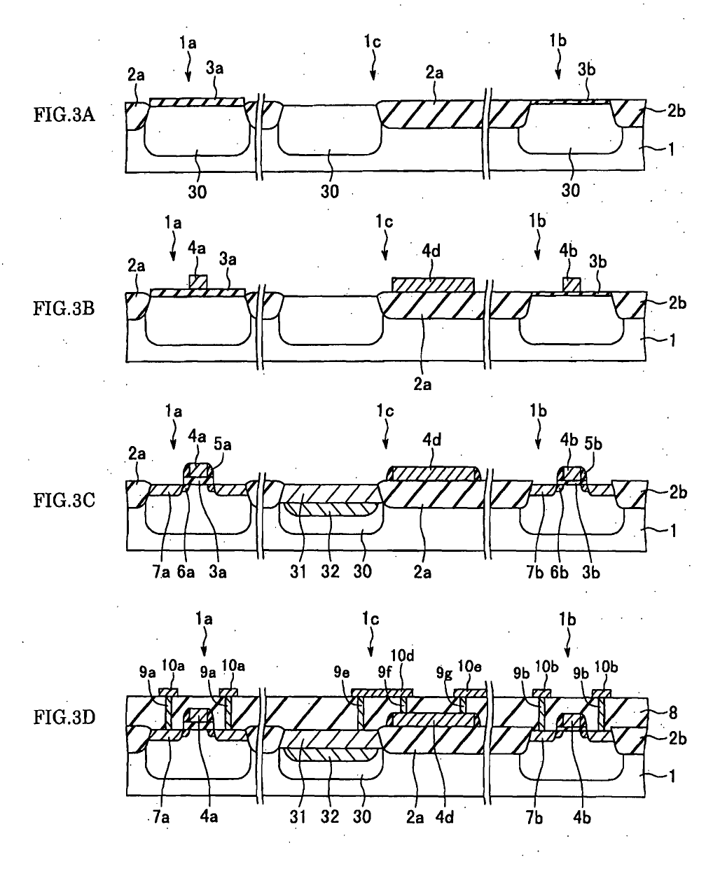

FIGS. 3A-3D are cross-sectional views for describing a method for manufacturing a semiconductor device in accordance with a second embodiment of the invention. The second embodiment is generally the same as the first embodiment except that, instead of a transistor, a diode is formed in the element region 1c. Compositions similar to those of the first embodiment are appended with the same reference numerals, and their description is omitted.

First, referring to FIG. 3A, wells 30, element isolation films 2a and 2b and gate dielectric films 3a and 3b are formed on a silicon substrate 1. In this instance, a thermal oxidation film is also formed on the silicon substrate located in the element region 1c. The forming method used for the above is generally the same as that of the first embodiment shown in FIG. 1A.

Then, referring to FIG. 3B, gate electrodes 4a and 4b, and a resistance element 4d are formed. The forming method used for the above is generally the same as that of the first embodiment shown in FIG. 1B, except that a gate electrode 4c is not formed.

Then, referring to FIG. 3C, the element regions 1a and 1b are covered by a mask film (not shown), and an impurity of a first conductivity type is introduced in the silicon substrate 1 by using the mask film as a mask. By this, an impurity region 32 of the first conductivity type is formed in the silicon substrate 1. Then, the mask film is removed.

Then, low concentration impurity regions 6a and 6b, sidewalls 5a and 5b and impurity regions 7a and 7b are formed. The forming method used for the above is generally the same as that of the first embodiment shown in FIG. 1C. Further, in the process of forming the low concentration impurity regions 6a and 6b and in the process of forming the impurity regions 7a and 7b, an impurity region 31 of a second conductivity type located above the impurity region 32 is formed in the silicon substrate 1 located in the element region 1c. The impurity region 31 forms, together with the impurity region 32 of the first conductivity type, a protection diode that discharges a high voltage noise current to the ground through the source potential of a transistor 40 in an output stage.

Then, referring to FIG. 3D, an interlayer dielectric film 8, tungsten plugs 9a, 9b, 9e, 9f and 9g, and Al alloy wirings 10a, 10b, 10d and 10e are formed. The forming method used for the above is generally the same as that of the first embodiment shown in FIG. 1D except that tungsten plugs 9c and 9d and an Al alloy wiring 10c are not formed. However, the tungsten plug 9e is connected to the impurity region 31, and the Al alloy wiring 10d is connected to the impurity region 31 and the resistance element 4d.

The semiconductor device shown in FIG. 3D has a circuit diagram in which the transistor in the element region 1c in the circuit diagram of FIG. 2 is replaced with a diode. The effects similar to those of the first embodiment can also be obtained by the second embodiment.

It is noted that the invention is not limited to the embodiments described above, and can be implemented with a variety of changes made thereto within the scope that does not depart from the subject matter of the invention. For example, the resistance element 4d may not be a part of the transistor protection circuit, but may be, for example, a resistance element to which a voltage of 10V or higher is applied during normal operation, whereby the above described effects can be obtained by application of the invention.

What is claimed is:

1. A semiconductor device comprising:
a first element isolation film that is formed by a LOCOS oxidation method on a semiconductor substrate for isolating a first element region from other regions;
a second element isolation film embedded in a groove formed in the semiconductor substrate for isolating a second element region from other regions;
a first semiconductor element formed in the first element region;
a second semiconductor element formed in the second element region; and
a resistance element formed on the first element isolation film.

2. A semiconductor device according to claim 1, wherein the first semiconductor element is connected to one end side of the resistance element, and the semiconductor device includes an external connection terminal formed above the semiconductor substrate, a wiring that connects another end side of the resistance element and the external connection terminal, and a discharge element formed on the semiconductor substrate and connected to the wiring for protecting the first semiconductor element by discharging a noise current applied from the external connection terminal to the ground.

3. A semiconductor device according to claim 2, wherein the first semiconductor element is a part of an on/off signal generation circuit that generates a signal that turns on and off a gate of a TFT provided outside the semiconductor substrate, and the second semiconductor element is a part of a control circuit that controls the on/off signal generation circuit.

4. A method for manufacturing a semiconductor device comprising the steps of:
isolating a first element region from other regions by forming a first element isolation film on a semiconductor substrate by using a LOCOS oxidation method;
isolating a second element region from other regions by forming a groove in the semiconductor substrate and embedding a second element isolation film in the groove;
forming a first semiconductor element in the first element region and forming a second semiconductor element in the second element region; and
forming a resistance element on the first element isolation film.

5. A method for manufacturing a semiconductor device according to claim 4, wherein the step of embedding the second element isolation film in the groove includes forming a dielectric film in the groove, on the first element isolation film and on the semiconductor substrate, and removing the dielectric film located on the first element isolation film and on the semiconductor substrate by a CMP method.
